(19) United States
(12) Patent Application Publication
(10) Pub. No.: US 2018/0366382 A1
(43) Pub. Date: Dec. 20, 2018

(54) CIRCUIT BOARD

(71) Applicant: NIDEC SANKYO CORPORATION, Suwa-gun Nagano (JP)

(72) Inventor: Mitsuo YOKOZAWA, Suwa-gun Nagano (JP)

(21) Appl. No.: 15/737,048

(22) PCT Filed: Jun. 9, 2016
(86) PCT No.: PCT/JP2016/067274

§ 371 Date: Dec. 15, 2017

(30) Foreign Application Priority Data
Jun. 17, 2015 (JP) 2015-122064

(51) Int. Cl. H01L 23/12; H05K 3/46; H05K 1/05; H05K 1/02; H05K 3/42; H01L 23/31; H01L 23/42; H05K 3/34

(52) U.S. Cl. CPC H01L 23/12; H05K 3/46; H05K 1/05; H05K 1/0206; H05K 2201/09563; H01L 23/3114; H01L 23/42; H05K 3/3436; H05K 3/425

(57) ABSTRACT

Provided is a circuit board capable of dissipating heat at a higher efficiency compared with conventional cases from an electronic component mounted at a high density. A circuit board has a first wiring layer and a second wiring layer, which are laminated on the front surface side of an aluminum base material. The second wiring layer is positioned between the first wiring layer and the base material. The first wiring layer is provided with a land having a BGA placed thereon and connected thereto, said BGA being a terminal of a wafer-level chip-size package. The land is electrically connected to the second wiring layer by means of a via-filling plating formed at a position overlapping the land when viewed from the lamination direction Z. Heat of the wafer-level chip-size package is transmitted to the base material via the land, the via-filling plating, and the second wiring layer, and is dissipated from the base material.

### CROSS REFERENCE TO RELATED APPLICATIONS

This is the U.S. national stage of application No. PCT/JP2016/067274, filed on Jun. 9, 2016. Priority under 35 U.S.C. § 119(a) and 35 U.S.C. § 365(b) is claimed from Japanese Application No. 2015-122064, filed Jun. 17, 2015; the disclosure of which is incorporated herein by reference.

### FIELD OF THE INVENTION

At least an embodiment of the present invention relates to a circuit board on which an electronic component is mounted.

### BACKGROUND

An electronic component mounted on an electronic device has required miniaturization and high-density mounting to a circuit board. A wafer level chip size package (WLCSP) has been proposed as a semiconductor package (electronic component) whose mounting area on a circuit board is small. A WLCSP is manufactured so that final processing in semiconductor assembling is performed in a wafer state and a size of a semiconductor chip obtained by cutting the wafer becomes a final size of the package. A ball grid array (BGA) has been known as a mounting technique for mounting a lot of electronic components on a narrow circuit board. In the BGA, a semiconductor chip is provided with solder balls as external terminals. In Patent Literature 1, a chip size package provided with the BGA is described.

### PATENT LITERATURE

[PTL 1] Japanese Patent Laid-Open No. Hei 11-67998

A temperature of the WLCSP may be increased due to its heat generation. Further, a surface area of the WLCSP is small and thus the temperature of the WLCSP is not lowered only through heat radiation of the WLCSP itself and the WLCSP may be damaged.

In order to avoid damage of the WLCSP, it is conceivable that heat of the WLCSP is radiated outside through a circuit board on which the WLCSP is mounted. However, a glass epoxy board which is commonly used as a circuit board is not provided with a coefficient of thermal conductivity capable of sufficiently radiating heat from a WLCSP.

### SUMMARY

In view of the problem described above, at least an embodiment of the present invention provides a circuit board which is capable of radiating heat from an electronic component mounted with high density with a higher degree of efficiency than conventional.

To achieve the above, at least an embodiment of the present invention provides a circuit board including a base member made of metal, and a first wiring layer and a second wiring layer which are laminated on a side of a front face of the base member and the second wiring layer is located between the first wiring layer and the base member. The first wiring layer is provided with a land on which a terminal of an electronic component is placed and connected, and the land is conducted to the second wiring layer by via-hole-filling plating which is formed at a position overlapped with the land when viewed in a laminated direction.

According to at least an embodiment of the present invention, heat generated from the electronic component is transmitted from its terminal to the second wiring layer through the land of the first wiring layer and the via-hole-filling plating of the circuit board. Further, the heat transmitted to the second wiring layer is radiated outside from the base member made of metal. In at least an embodiment of the present invention, the base member of the circuit board is made of metal. Therefore, in comparison with a conventional circuit board whose base member is made of glass epoxy resin, heat generated from the electronic component can be sufficiently radiated through the base member. Further, according to at least an embodiment of the present invention, a plurality of wiring layers is laminated on the side of the front face of the base member and thus wiring pattern can be provided three-dimensionally and high-density mounting of the electronic component is easily performed. In addition, the laminated wiring layers are connected with each other through a via-hole-filling plating formed at a position overlapped with the land and thus heat transmitted from the electronic component to the land is transmitted to the second wiring layer which is located close to the base member in a shortest path. Therefore, the heat of the electronic component can be efficiently radiated through the base member.

In at least an embodiment of the present invention, it may be structured that the electronic component is a wafer level chip size package (WLCSP), and a ball grid array (BGA) is provided as the terminal. Since a surface area of the WLCSP is small, heat radiation is not sufficient and thus damage may be occurred due to heat generated in itself. However, when heat from the WLCSP is radiated through the circuit board, damage of the WLCSP can be prevented.

In at least an embodiment of the present invention, it is desirable that an occupancy ratio of copper foil forming the second wiring layer occupying a front face of the base member is larger than an occupancy ratio of copper foil forming the first wiring layer occupying the front face of the base member. According to this structure, heat transmitted from a terminal of the electronic component to the second wiring layer through the land of the first wiring layer and the via-hole-filling plating can be diffused to the entire base member and thus radiation of heat from the base member is promoted.

In at least an embodiment of the present invention, the land may be structured so as to be conducted to the second wiring layer through a plurality of via-hole-filling platings. When the land and the second wiring layer are conducted to each other through a plurality of via-hole-filling platings, heat from the electronic component is easily transmitted from the land to the second wiring layer.

In at least an embodiment of the present invention, it is desirable that the first wiring layer is provided with a dummy land which is connected with an unused terminal that is not required to be electrically connected among terminals of the electronic component, and the dummy land is connected with the second wiring layer through dummy land via-hole-filling plating which is formed at a position overlapped with the dummy land when viewed in the laminated direction. According to this structure, heat generated from the electronic component can be transmitted to the second wiring layer through the unused terminal, the dummy land, and the dummy land via-hole-filling plating and radiated from the base member.

In at least an embodiment of the present invention, it is desirable that the circuit board includes an insulating layer between the second wiring layer and the base member, and the insulating layer contains aluminum oxide, aluminum nitride, boron nitride, magnesium nitride, silicon nitride, titanium nitride or calcium nitride, or a compound thereof. According to this structure, heat conductivity of the insulating layer can be increased. Therefore, the heat from the second wiring layer to the base member can be transmitted efficiently.

In at least an embodiment of the present invention, it is desirable that the circuit board includes a third wiring layer which is provided between the first wiring layer and the second wiring layer, and the via-hole-filling plating is provided with first via-hole-filling plating which is formed at a position overlapped with the land when viewed in the laminated direction to conduct the first wiring layer to the third wiring layer, and second via-hole-filling plating which is formed at a position overlapped with the first via-hole-filling plating when viewed in the laminated direction to conduct the third wiring layer to the second wiring layer. When the wiring layer is structured in a further multi-layered manner, the wiring pattern can be further three-dimensionally provided and thus high-density mounting of an electronic component is easily performed. Further, the first wiring layer, the third wiring layer and the second wiring layer are connected with each other through the via-hole-filling plating (first via-hole-filling plating and second via-hole-filling plating) provided at the position overlapped with the land. Therefore, heat transmitted from the electronic component to the land of the first wiring layer is transmitted to the second wiring layer which is located close to the base member in a shortest path. Accordingly, even in a case that the wiring layer is structured in a further multi-layered manner, lowering of transmission efficiency of heat from the first wiring layer provided with the land to the second wiring layer located close to the base member can be suppressed.

In order to manufacture the circuit board, first, a plurality of wiring patterns for the circuit board is formed on one large-sized base member and a large-sized circuit board including the wiring patterns and insulating layers for each circuit board is manufactured. After that, the large-sized circuit board is divided to obtain a target circuit board. In the manufacturing method, in order to divide the large-sized circuit board, a “V”-shaped groove is formed on a front face and a rear face of the large-sized circuit board at positions overlapped with each other to section regions of the wiring patterns and the insulating layers for respective circuit boards. After that, stress is applied to the large-sized circuit board to divide it along the “V”-shaped groove and a target circuit board is obtained. Therefore, the circuit board manufactured by using the above-mentioned manufacturing method is provided with inclined faces corresponding to the “V”-shaped grooves on an outer peripheral edge portion of the front and rear faces of the base member. In other words, the base member is provided with a front face side inclined face which is inclined to a side of the rear face as going toward an outer peripheral side in the front face side outer peripheral edge portion formed along an outer peripheral edge of the front face of the base member, and a rear face side inclined face which is inclined to a side of the front face as going to the outer peripheral side in the rear face side outer peripheral edge portion formed along an outer peripheral edge of the rear face of the base member.

In the circuit board manufactured by using the manufacturing method described above, in order to easily secure a mounting area of an electronic component, the base member is provided with a front face side inclined face which is inclined to a side of a rear face of the base member as going toward an outer peripheral side in a front face side outer peripheral edge portion having a first width dimension formed along an outer peripheral edge of the front face, and a rear face side inclined face which is inclined to a side of the front face as going to the outer peripheral side in the rear face side outer peripheral edge portion having a second width dimension formed along an outer peripheral edge of the rear face, and the first width dimension is shorter than the second width dimension. In other words, when the “V”-shaped groove formed on the side of the front face of the circuit board is formed to be smaller than the “V”-shaped groove formed on the side of the rear face for dividing the large-sized circuit board, a mounting area of an electronic component can be easily secured.

In at least an embodiment of the present invention, it may be structured that the base member is made of aluminum. According to this structure, a circuit board whose weight is light and whose heat conductivity is high can be used.

In at least an embodiment of the present invention, it may be structured that the base member is provided with a fixing part structured to fix a motor. In other words, in a case that the base member is made of glass epoxy resin or the like, the circuit board is required to provide a fixing part made of metal for mounting a motor on the circuit board. However, in at least an embodiment of the present invention, since the base member is made of metal, a fixing part for fixing a motor can be provided in the base member. Therefore, the number of components can be reduced.

According to the circuit board in accordance with at least an embodiment of the present invention, heat from the electronic component mounted with high density can be radiated with a high degree of efficiency in comparison with a conventional circuit board made of glass epoxy resin.

### BRIEF DESCRIPTION OF DRAWINGS

Embodiments will now be described, by way of example only, with reference to the accompanying drawings which are meant to be exemplary, not limiting, and wherein like elements are numbered alike in several Figures, in which:

FIG. 1 is a perspective view showing a motor unit including a circuit board in accordance with at least an embodiment of the present invention.

FIGS. 2A and 2B are a cross-sectional view of a motor unit and an explanatory view showing an internal structure of a motor.

FIGS. 3A and 3B are explanatory views showing a circuit board on which a WLCSP is mounted.

FIGS. 4A through 4D are explanatory views showing a manufacturing method for a circuit board and a motor unit.

FIGS. 5A through 5D are explanatory views showing a manufacturing method for a circuit board and a motor unit.

FIGS. 6A through 6C are explanatory views showing a manufacturing method for a circuit board and a motor unit.

FIGS. 7A and 7B are explanatory views showing circuit boards in a first and a second modified embodiments.

### DETAILED DESCRIPTION

A circuit board to which at least an embodiment of the present invention is applied will be described below with reference to the accompanying drawings.

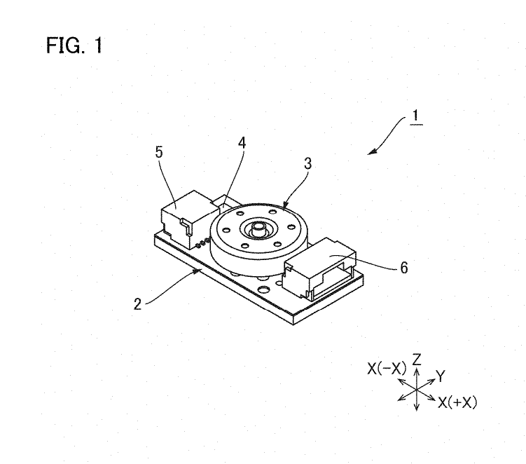

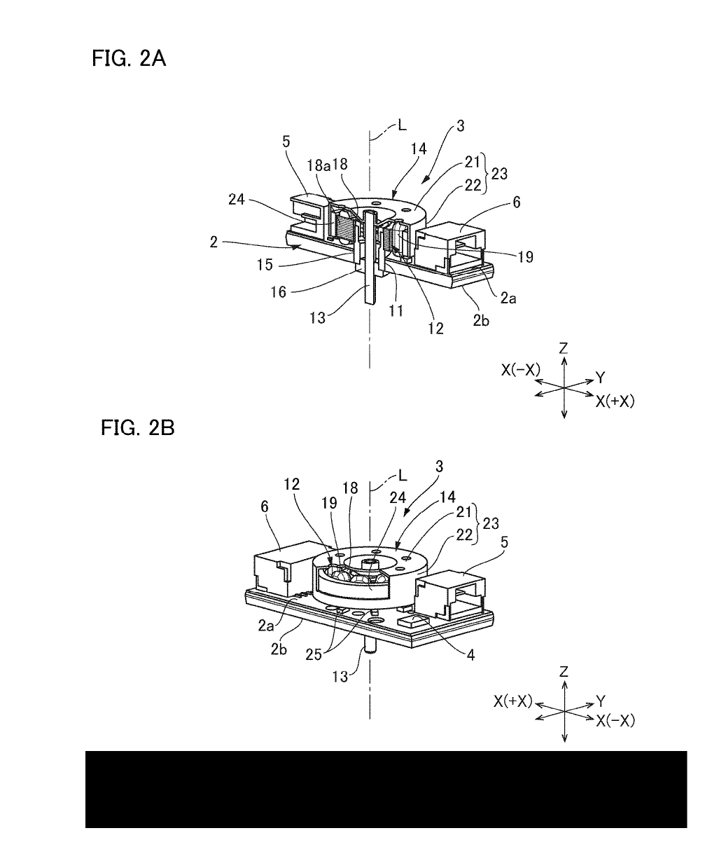

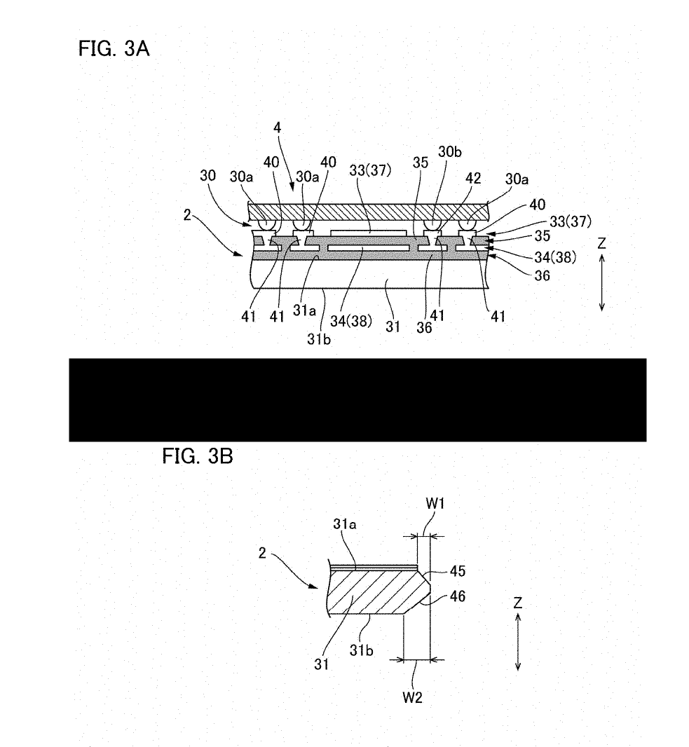

FIG. 1 is a perspective view showing a motor unit including a circuit board in accordance with at least an embodiment of the present invention. FIG. 2A is a cross-sectional view of a motor unit and FIG. 2B is an explanatory view showing a structure of a motor. FIGS. 3A and 3B are explanatory views showing a mount portion of a wafer level chip size package in a circuit board.

As shown in FIG. 1, a motor unit 1 includes a circuit board 2 formed in a rectangular shape, a motor 3 which is attached in a center portion of the circuit board 2, and a wafer level chip size package (WLCSP) 4 which is mounted on one side with respect to the motor 3 in a long-side direction “X” of the circuit board 2. Further, the motor unit 1 includes a first connector 5 and a second connector 6 which are attached on both sides of the motor 3 in the long-side direction “X”. The first connector 5 is fixed to a first direction “−X” in the long-side direction “X” with respect to the motor 3, and the second connector 6 is fixed to a second direction “+X” in the long-side direction “X” with respect to the motor 3. In FIG. 2A, the motor unit 1 is viewed from the second direction “+X” side and, in FIG. 2B, the motor unit 1 is viewed from the first direction “−X” side. In FIG. 2B, a rotor main body structuring the motor 3 is partly cut out.

The circuit board 2 is structured so that a multilayered wiring layer is formed by a build-up method on one face (front face) of a base member made of aluminum. A dimension in the long-side direction “X” of the circuit board 2 is about 3 cm and a dimension in its short-side direction “Y” is about 1.5 cm and thus the circuit board 2 is small. A fixing hole 11 (fixing part) for fixing the motor 3 is provided in a center portion of the circuit board 2 as shown in FIG. 2A.

The motor 3 is a three-phase permanent magnet synchronous motor (PMSM). The motor 3 includes a stator 12, a rotor 14 having an output shaft 13, a sleeve 15 which supports the stator 12 in a state that the sleeve 15 is penetrated through the fixing hole 11, and a bearing 16 which is fixed to the sleeve 15. An axial line “L” of the motor 3 (rotation center line of the output shaft 13) is extended in a laminated direction “Z” perpendicular to the circuit board 2.

The stator 12 includes a ring-shaped stator core 18 provided with a plurality of salient poles 18a protruded in a radial direction, and stator coils 19 which are wound around the respective salient poles 18a. The stator core 18 is disposed on a side of the front face 2a of the circuit board 2. A front face side protruded portion of the sleeve 15 which is protruded to the side of the front face 2a of the circuit board 2 is inserted into a center hole of the stator core 18. In this manner, the stator core 18 is fixed to the circuit board 2 through the sleeve 15.

The rotor 14 includes a rotor main body 23, which is provided with a circular bottom plate part 21 and a ring-shaped plate part 22 extended from an outer peripheral edge portion of the bottom plate part 21 toward a side of the circuit board 2, and a rotor magnet 24 which is fixed to an inner peripheral face of the ring-shaped plate part 22. The output shaft 13 is fixed to the center of the bottom plate part 21 and is extended on an inner side of the ring-shaped plate part 22 so as to be coaxial with the rotor main body 23. The output shaft 13 is protruded from a circular opening part (opening on the side of the circuit board 2) of the rotor main body 23.

The rotor 14 is assembled in a state that the stator core 18 is covered with the rotor main body 23 from the side of the front face 2a of the circuit board 2, the output shaft 13 is inserted into the sleeve 15, and a tip end portion of the output shaft 13 is protruded from the sleeve 15 to the side of the rear face 2b of the circuit board 2. As a result, the salient poles of the stator core 18 and the rotor magnet 24 face each other. Further, the rotor magnet 24 faces Hall elements 25 mounted on the front face 2a of the circuit board 2 with a narrow space therebetween.

The bearing 16 is fixed to an end portion of the sleeve 15 on the side of the rear face 2b of the circuit board 2. The bearing 16 rotatably supports the output shaft 13 (rotor 14) around the axial line “L”.

The WLCSP 4 includes a driver circuit for driving the motor 3, a controller circuit for controlling drive of the motor 3, and an amplifier circuit. Therefore, the motor unit 1 in this embodiment is structured so that the motor 3 and a control circuit board for the motor 3 are integrated with each other. Further, the WLCSP 4 includes a ball grid array (BGA) 30 (see FIG. 3A). In other words, the WLCSP 4 includes solder balls as terminals 30a on its wafer.

### (Detailed Structure of Circuit Board)

FIG. 3A is a cross-sectional view schematically showing a portion of the circuit board 2 on which the WLCSP 4 is mounted, and FIG. 3B is a cross-sectional view schematically showing an outer peripheral edge portion of the circuit board 2. As shown in FIG. 3A, the circuit board 2 includes a first wiring layer 33 and a second wiring layer 34 which are laminated on a side of a front face 31a of a base member 31. The second wiring layer 34 is located between the first wiring layer 33 and the base member 31. A first insulating layer 35 is provided between the first wiring layer 33 and the second wiring layer 34. A second insulating layer (insulating layer) 36 is provided between the second wiring layer 34 and the base member 31.

The first wiring layer 33 is provided with a first wiring pattern 37. The second wiring layer 34 is provided with a second wiring pattern 38. An occupancy ratio of the second wiring pattern 38 (copper foil) forming the second wiring layer 34 occupying the front face 31a of the base member 31 is larger than an occupancy ratio of the first wiring pattern 37 (copper foil) forming the first wiring layer 33 occupying the front face 31a of the base member 31. In this embodiment, an occupancy ratio of the second wiring pattern 38 forming the second wiring layer 34 which occupies the front face 31a of the base member 31 is 80%-90%. Therefore, the second wiring pattern 38 is provided so as to cover most of the front face 31a of the base member 31.

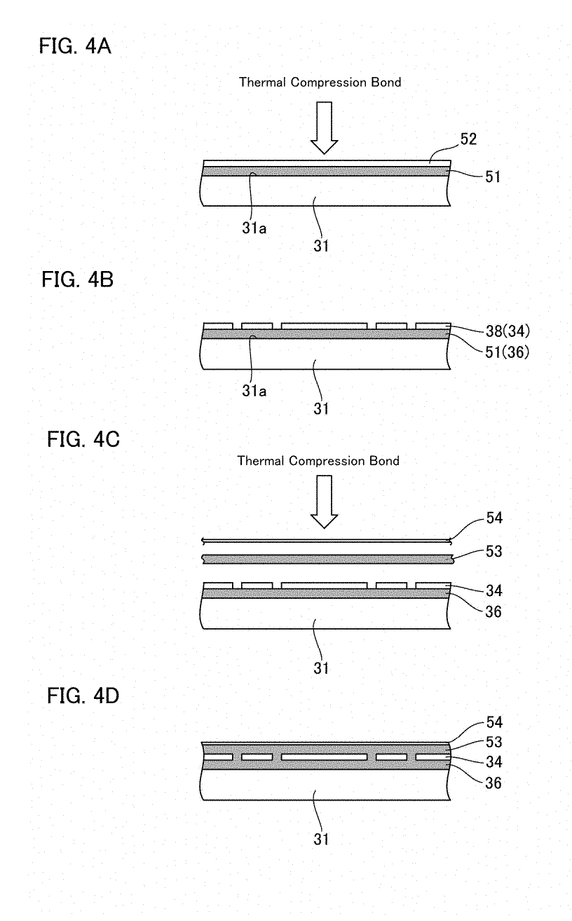

The first insulating layer 35 and the second insulating layer 36 are formed of an insulating adhesive film (see FIGS. 4A through 4D described below). Alumina powder (aluminum oxide) is added to the insulating adhesive film and its thermal conductivity is increased. In this embodiment, an insulating adhesive film may be used in which aluminum oxide, aluminum nitride, boron nitride, magnesium nitride, silicon nitride, titanium nitride or calcium nitride is added or one of these compounds is added and its thermal conductivity is increased. In accordance with an embodiment of the present invention, the insulating adhesive film 53 forming the first insulating layer 35 and the insulating adhesive film 51 forming the second insulating layer 36 may be the same film as each other, or may be different films from each other. In this embodiment, the same film is used.

The first wiring pattern 37 of the first wiring layer 33 is provided with lands 40 which are connected with the Hall elements 25, the WLCSP 4, the connectors 5 and 6, and the like. As shown in FIG. 3A, the BGA 30 as the terminals 30a of the WLCSP 4 is connected and placed on the lands 40. A plurality of lands 40 among the lands 40 connected with the terminals 30a of the WLCSP 4 is conducted to the second wiring layer 34 by via-hole-filling plating 41 formed at positions overlapped with the lands 40 when viewed in the “Z” direction (laminated direction) perpendicular to the base member 31.

Further, the first wiring pattern 37 is provided with a dummy land 42 on which an unused terminal 30b which is not required to be electrically connected is placed and connected among the plurality of the terminals of the WLCSP 4. The dummy land 42 is conducted to the second wiring layer 34 by via-hole-filling plating (dummy land via-hole-filling plating) 41 formed at a position overlapped with the dummy land 42 when viewed in the direction (laminated direction) perpendicular to the base member 31.

In this embodiment, the 50% or more lands 40 of the lands 40 (including dummy land 42) with which the terminals 30a of the WLCSP 4 are connected are conducted to the second wiring layer 34 by the via-hole-filling plating 41 formed at the positions overlapped with the respective lands 40.

As shown in FIG. 3B, the base member 31 is provided with a front face side inclined face 45 which is inclined to the side of the rear face 31b of the base member 31 toward an outer peripheral side in a front face side outer peripheral edge portion having a first width dimension “W1” along an outer peripheral edge of the front face 31a. Further, the base member 31 is provided with a rear face side inclined face 46, which is inclined to the side of the front face 31a of the base member 31 toward the outer peripheral side in a rear face side outer peripheral edge portion having a second width dimension along an outer peripheral edge of the rear face 2b. An inclination angle of the front face side inclined face 45 with respect to the front face 31a of the base member 31 and an inclination angle of the rear face side inclined face 46 with respect to the rear face 31b of the base member 31 are equal to each other, and the first width dimension “W1” is shorter than the second width dimension “W2”. Therefore, the rear face side inclined face 46 is reached to a deeper position in a thickness direction of the base member 31 than the front face side inclined face 45.

### (Manufacturing Method for Circuit Board and Motor Unit)

FIGS. 4A through 6C are explanatory views showing a manufacturing method for the circuit board 2 and the motor unit. When the circuit board 2 is to be manufactured, first, a plurality of the first wiring patterns 37 and a plurality of the second wiring patterns 38 for the circuit boards 2 are formed and arranged laterally and longitudinally on one large-sized base member 31 to obtain a large-sized circuit board 50. After that, the large-sized circuit board 50 is divided and target circuit boards 2 are obtained.

More specifically, as shown in FIG. 4A, an insulating adhesive film 51 and a copper foil 52 are laminated on a front face 31a of the large-sized base member 31 in this order and they are thermally compression-bonded to each other. After that, as shown in FIG. 4B, second wiring patterns 38 are formed by patterning (etching) the copper foil 52. As a result, a second insulating layer 36 and a second wiring layer 34 are formed.

Next, as shown in FIG. 4C, an insulating adhesive film 53 and a copper foil 54 are laminated on the second wiring layer 34 in this order and they are thermally compression-bonded. As a result, a state shown in FIG. 4(d) is obtained. In this embodiment, the copper foil 54 laminated on the second wiring layer 34 is a foundation for a first wiring layer 33 and the copper foil 54 is thinner than the copper foil 52 used for forming the second wiring layer 34.

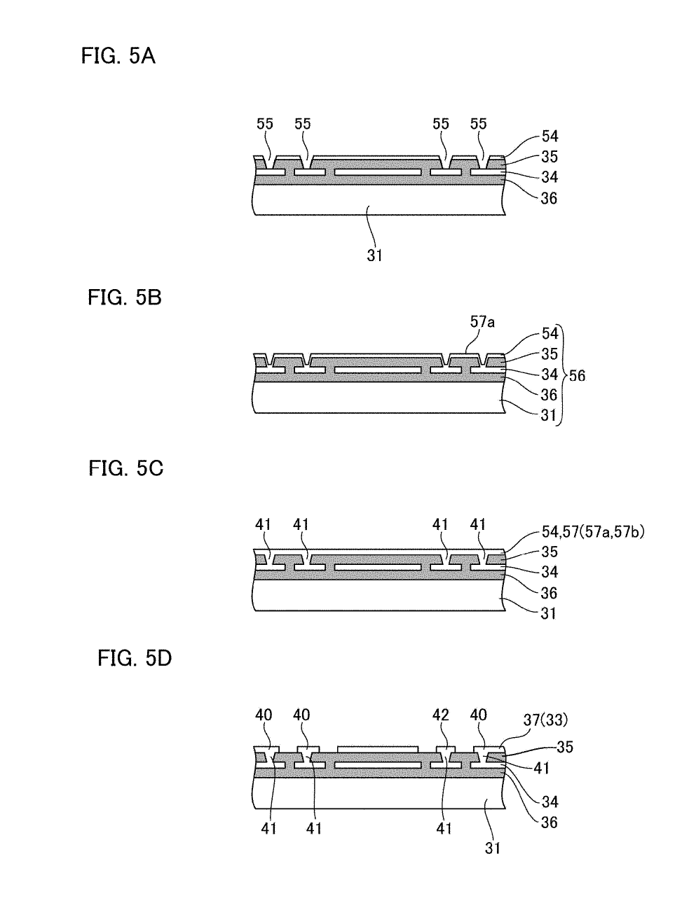

After that, blackening processing is performed on the copper foil 54 and, as shown in FIG. 5A, via holes 55 reaching the second wiring layer 34 are formed in the copper foil 54 and the insulating adhesive film 53 by laser beam processing. A first insulating layer 35 is formed by forming the via holes 55 in the insulating adhesive film 53 (the first insulating adhesive film 53 becomes the insulating layer 35).

After that, as shown in FIG. 5B, electroless copper plating 57a is performed on a front face 31a of a laminated body 56 comprised of the base member 31, the second insulating layer 36, the second wiring layer 34, the first insulating layer 35 and the copper foil 54. Further, copper plating 57b is further performed on the electroless copper plating 57a.

In this manner, as shown in FIG. 5C, the second wiring layer 34 and a front side layer (first wiring layer 33 before patterning is performed) comprised of the copper foil 54 and the copper plating 57 (electroless copper plating 57a and copper plating 57b) are brought into a conductive state by the via-hole-filling plating 41 performed on inner peripheral faces of the via holes 55. Further, the front side layer comprised of the copper foil 54 and the electroless copper plating 57a is formed so as to have a thickness dimension similar to that of the copper foil 52 forming the second wiring layer 34. In accordance with an embodiment of the present invention, the second wiring layer 34 and the first wiring layer 33 may be conducted to each other by pad-on-via. However, when the second wiring layer 34 and the first wiring layer 33 are conducted to each other by via-hole-filling plating 41, a work for filling the via holes 55 with resin like pad-on-via is not required. Therefore, the circuit board 2 can be easily manufactured. Further, heat is easily transmitted through via-hole-filling plating 41 in comparison with pad-on-via.

After that, patterning (etching) is performed on the front side layer comprised of the copper foil 54 and the copper plating 57 to form the first wiring patterns 37. As a result, the first wiring layer 33 is formed as shown in FIG. 5(d).

The first wiring pattern 37 is provided with lands 40 with which the Hall elements 25, the WLCSP 4, the connectors 5 and 6, and the like are connected. Further, the first wiring pattern 37 is provided with a dummy land 42. In this embodiment, 50% or more lands of the lands (land 40 and dummy land 42) with which the WLCSP 4 is connected are overlapped with the via-hole-filling plating 41 when viewed in a direction (laminated direction Z) perpendicular to the circuit board 2.

After that, if necessary, surface treatments such as coating of a solder resist, silk screen printing and solder plating are performed. As a result, a large-sized circuit board 50 is completed.

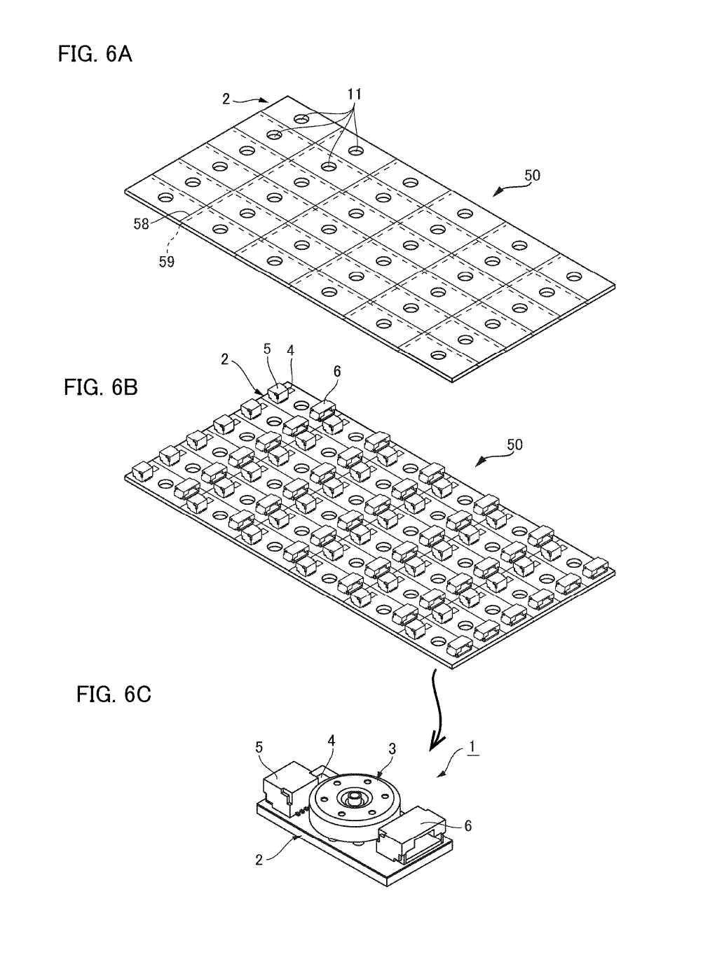

Next, the large-sized circuit board 50 is mechanically worked. In other words, as shown in FIG. 6A, a plurality of the fixing holes 11 is formed in the large-sized circuit board 50. Further, in order to divide the large-sized circuit board 50, “V”-shaped grooves 58 and 59 are formed on front and rear faces of the large-sized circuit board 50 at positions overlapped with each other and a region of the first wiring pattern 37, the second wiring pattern 38, the first insulating layer 35 and the second insulating layer 36 for each circuit board 2 is sectioned. In a case that the “V”-shaped grooves 58 and 59 are to be formed, the front face side “V”-shaped groove 58 formed on the front side of the large-sized circuit board 50 in which the first wiring layer 33 and the second wiring layer 34 are provided is formed shallower than the rear face side “V”-shaped groove 59 formed on the rear side face of the large-sized circuit board 50. When the front face side “V”-shaped grooves 58 and the rear face side “V”-shaped grooves 59 are formed, the large-sized circuit board 50 is structured in a state that a plurality of the circuit boards 2 to be obtained is connected laterally and longitudinally through the front face side “V”-shaped grooves 58 and the rear face side “V”-shaped grooves 59.

Next, as shown in FIG. 6B, electronic components are mounted on respective circuit boards 2. In other words, the Hall elements 25, the WLCSP 4, the connectors 5 and 6 and other electronic components not shown are placed with respect to the first wiring pattern 37 and they are connected with each other through the first wiring pattern 37 and the second wiring pattern 38. After that, stress is applied to the large-sized circuit board 50 and the large-sized circuit board 50 is divided into the respective circuit boards 2 along the front face side “V”-shaped grooves 58 and the rear face side “V”-shaped grooves 59.

After that, the motor 3 is assembled on each of the circuit boards 2 by utilizing the fixing hole 11. As a result, as shown in FIG. 6C, the motor unit 1 is completed.

### Operations and Effects

According to this embodiment, heat of the WLCSP 4 is transmitted from the lands 40 of the first wiring layer 33 of the circuit board 2 to the second wiring layer 34 through the via-hole-filling plating 41. Further, the heat of the WLCSP 4 is transmitted from the lands 40 to the second wiring layer 34 through the first insulating layer 35 (insulating adhesive film 53) having high heat conductivity. Then, the heat transmitted to the second wiring layer 34 is transmitted to the base member 31 made of aluminum through the second insulating layer 36 (insulating adhesive film 51) having high heat conductivity and the heat is radiated outside from the base member 31. Therefore, in comparison with a conventional circuit board 2 whose base member 31 is made of glass epoxy resin, heat of the WLCSP 4 can be sufficiently radiated through the base member 31.

Further, in this embodiment, a plurality of wiring layers 33 and 34 is laminated on the side of the front face 31a of the base member 31 and thus wiring patterns can be provided three-dimensionally. Therefore, high-density mounting of electronic components is easily performed and mounting of the WLCSP 4 provided with a large number of terminals 30a in a narrow region is also easily performed.

In addition, in this embodiment, the laminated wiring layers are connected with each other through the via-hole-filling plating 41 formed at the position overlapped with the land 40. Therefore, heat transmitted from the WLCSP 4 to the land 40 is transmitted to the second wiring layer 34 which is located on a side close to the base member 31 in a shortest path. Accordingly, heat radiation through the base member 31 can be performed efficiently.

Further, in this embodiment, unused BGA 30 among the BGA 30 of the WLCSP 4 which is not required to be electrically connected is connected with dummy lands 42. Therefore, heat of the WLCSP 4 can be transmitted from the dummy lands 42 to the second wiring layer 34 through the via-hole-filling platings 41. Accordingly, the heat of the WLCSP 4 can be further effectively radiated from the base member 31.

In addition, in this embodiment, an occupancy ratio of the second wiring pattern 38 (copper foil forming the second wiring layer 34) which occupies the front face 31a of the base member 31 is larger than an occupancy ratio of the first wiring pattern 37 (copper foil forming the first wiring layer 33) which occupies the front face 31a of the base member 31, and the occupancy ratio of the second wiring pattern 38 is set to be 80%-90% of the front face 31a of the base member 31. Therefore, heat transmitted from the BGA 30 of the WLCSP 4 to the second wiring layer 34 through the lands 40 of the first wiring layer 33 and the dummy lands 42 and the via-hole-filling platings 41 can be diffused to the entire base member 31 and thus radiation of the heat from the base member 31 is promoted.

In this embodiment, when a state is simulated in which heat of the WLCSP 4 mounted on the circuit board 2 is radiated by natural convection in a steady state of electric power consumption 0.73 W under an environment of 27° C., in a case that heat conductivity of the insulating layer is 10 W/m˜K, an attained highest temperature of the WLCSP 4 was 68.12° C. and an attained highest temperature of a portion of the circuit board 2 where the temperature is the lowest was 61.80° C. Further, in a case that heat conductivity of the insulating layer is 5 W/m˜K, an attained highest temperature of the WLCSP 4 was 70.57° C. and an attained highest temperature of a portion of the circuit board 2 where the temperature is the lowest was 61.76° C. In addition, in a case that heat conductivity of the insulating layer is 0.5 W/m·K which is similar to material structuring a glass epoxy board, an attained highest temperature of the WLCSP 4 was 125.93° C. and an attained highest temperature of a portion of the circuit board 2 where the temperature is the lowest was 60.95° C. In this case, it can be easily understood that temperature rise of the WLCSP 4 mounted on a glass epoxy board is further increased.

As described above, in this embodiment, a temperature difference between the WLCSP 4 and the circuit board 2 is small and the attained highest temperature of the WLCSP 4 is also low. Therefore, it is recognized that heat of the WLCSP 4 is efficiently radiated through the circuit board 2.

Further, in this embodiment, the “V”-shaped grooves 58 and 59 which are used for dividing one large-sized circuit board 50 into the circuit boards 2 to be obtained are structured so that the front face side “V”-shaped groove 58 formed on the front face side of the large-sized circuit board 50 where the first wiring layer 33 and the second wiring layer 34 are provided is set to be shallower than the rear face side “V”-shaped groove 59 formed on the rear face side of the large-sized circuit board 50. As a result, a width of the front face side inclined face 45 provided in an outer peripheral edge portion of the front face 31a of the base member 31 can be made narrower than a width of the rear face side inclined face 46 provided in an outer peripheral edge portion of the rear face 31b of the base member 31. Therefore, a mounting area of electronic components is easily secured on the front face 31a of the base member 31.

In addition, the base member 31 is made of aluminum and thus a weight of the circuit board 2 is light and its heat conductivity is high.

In a case that the base member 1 is made of glass epoxy resin or the like, a fixing part made of metal is required to provide for mounting the motor 3 on a circuit board. On the other hand, in this embodiment, the base member 31 is made of aluminum and thus a fixing part (fixing hole 11) for fixing the motor 3 can be directly provided in the base member 31. Therefore, the number of components can be reduced.

### Modified Embodiments

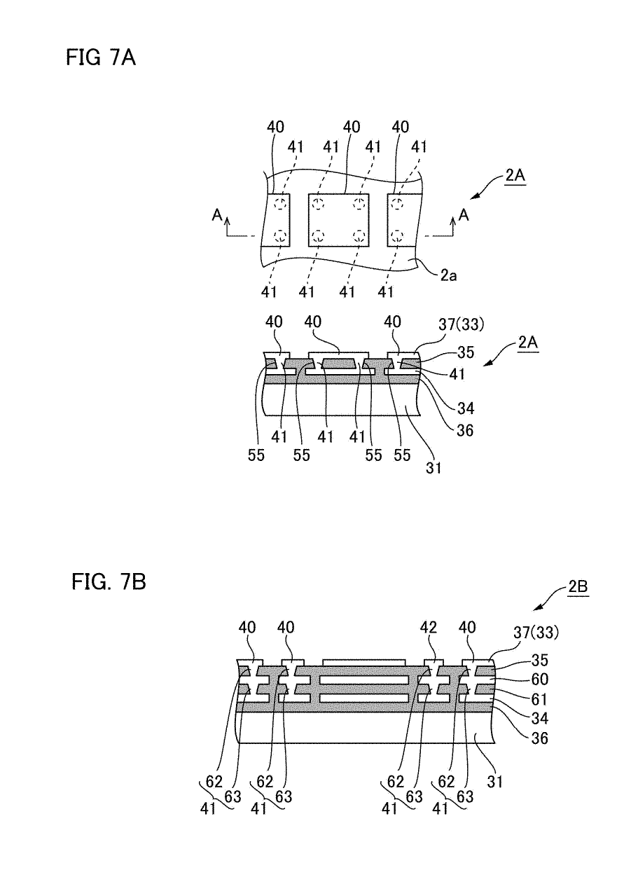

FIGS. 7A and 7B are explanatory views showing circuit boards in a first and a second modified embodiments. An upper side view in FIG. 7A is a plan view showing lands 40 of a circuit board in a first modified embodiment, and a lower side view in FIG. 7A is a cross-sectional view showing the circuit board in the first modified embodiment which is cut by the “A-A” line in the upper side view. FIG. 7B is a cross-sectional view showing a circuit board in a second modified embodiment.

In the circuit board 2A in the first modified embodiment, a land 40 is conducted to the second wiring layer 34 through a plurality of via-hole-filling platings 41. More specifically, as shown in FIG. 7A, a land 40 corresponding to the BGA 30 of the WLCSP 4 is formed in a quadrangular shape, and via holes 55 are separately provided from each other at four corners of the land 40, and the land 40 and the second wiring layer 34 are conducted to each other through via-hole-filling platings 41 applied to the respective via holes 55. In this case, when the land 40 and the second wiring layer 34 are conducted to each other through a plurality of the via-hole-filling platings 41, heat of the WLCSP 4 is easily transmitted from the land 40 to the second wiring layer 34.

Three wiring layers are provided in the circuit board 2B in the second modified embodiment. In other words, the circuit board 2B includes a third wiring layer 60 and a third insulating layer 61 between the first wiring layer 33 and the second wiring layer 34. More specifically, the circuit board 2B includes the second insulating layer 36, the second wiring layer 34, the third insulating layer 61, the third wiring layer 60, the first insulating layer 35 and the first wiring layer 33, which are laminated in this order from a side of the base member 31. Further, the circuit board 2B includes, as via-hole-filling plating 41, the first via-hole-filling plating 62 formed at a position overlapping with the land 40 when viewed in the laminated direction “Z” and electrically connecting the first wiring layer 33 with the third wiring layer 60, and the second via-hole-filling plating 63 formed at a position overlapping with the first via-hole-filling plating 62 when viewed in the laminated direction “Z” and electrically connecting the third wiring layer 60 with the second wiring layer 34.

When the wiring layer is multi-layered, the wiring pattern can be provided further three-dimensionally and thus high-density mounting of electronic components such as the WLCSP 4 is easily performed. Further, the first wiring layer 33, the third wiring layer 60 and the second wiring layer 34 are connected with each other through the via-hole-filling plating 41 (first via-hole-filling plating 62 and second via-hole-filling plating 63) provided at the position overlapped with the land 40 and thus heat transmitted from the WLCSP 4 to the lands 40 of the first wiring layer 33 is transmitted to the second wiring layer 34 located on the side close to the base member 31 in a shortest path. Therefore, even in a case that the wiring layer is further multi-layered, lowering of transmission efficiency of heat from the first wiring layer 33 provided with the lands 40 to the second wiring layer 34 located at a position close to the base member 31 can be suppressed.

### Other Embodiments

In the embodiment described above, the base member 31 is made of aluminum. However, for example, the base member 31 may be made of copper, brass or the like.

In accordance with an embodiment of the present invention, a heat sink may be attached to the base member 31 to promote heat radiation from the base member 31. Further, it may be structured that a liquid flow passage is provided in the base member 31 and cooling water is supplied to the liquid flow passage.

While the description above refers to particular embodiments of the present invention, it will be understood that many modifications may be made without departing from the spirit thereof. The accompanying claims are intended to cover such modifications as would fall within the true scope and spirit of the present invention.

The presently disclosed embodiments are therefore to be considered in all respects as illustrative and not restrictive, the scope of the invention being indicated by the appended claims, rather than the foregoing description, and all changes which come within the meaning and range of equivalency of the claims are therefore intended to be embraced therein.

1. A circuit board for use with an electronic component, the circuit board comprising:
a base member made of metal; and
a first wiring layer and a second wiring layer which are laminated on a side of a front face of the base member, the second wiring layer being located between the first wiring layer and the base member;
wherein the first wiring layer comprises a land on which a terminal of the electronic component is placed and connected; and
wherein the land is conducted to the second wiring layer by via-hole-filling plating which is formed at a position overlapped with the land when viewed in a laminated direction.

2. The circuit board according to claim 1, wherein the electronic component is a wafer level chip size package, and a ball grid array is provided as the terminal.

3. The circuit board according to claim 1, wherein an occupancy ratio of copper foil forming the second wiring layer occupying a front face of the base member is larger than an occupancy ratio of copper foil forming the first wiring layer occupying the front face of the base member.

4. The circuit board according to claim 3, wherein the land is conducted to the second wiring layer through a plurality of via-hole-filling platings.

5. The circuit board according to claim 3, wherein
the first wiring layer comprises a dummy land which is connected with an unused terminal among terminals of the electronic component, and
the dummy land is connected with the second wiring layer through dummy land via-hole-filling plating which is formed at a position overlapped with the dummy land when viewed in the laminated direction.

6. The circuit board according to claim 1, further comprising an insulating layer between the second wiring layer and the base member,
wherein the insulating layer contains aluminum oxide, aluminum nitride, boron nitride, magnesium nitride, silicon nitride, titanium nitride or calcium nitride, or a compound thereof.

7. The circuit board according to claim 1, further comprising a third wiring layer which is provided between the first wiring layer and the second wiring layer,
wherein the via-hole-filling plating comprises:
first via-hole-filling plating which is formed at a position overlapped with the land when viewed in the laminated direction to conduct the first wiring layer to the third wiring layer; and
second via-hole-filling plating which is formed at a position overlapped with the first via-hole-filling plating when viewed in the laminated direction to conduct the third wiring layer to the second wiring layer.

8. The circuit board according to claim 1, wherein
the base member comprises:
a front face side inclined face which is inclined to a side of a rear face of the base member as going toward an outer peripheral side, the front face side inclined face being formed in a front face side outer peripheral edge portion having a first width dimension formed along an outer peripheral edge of the front face; and
a rear face side inclined face which is inclined to a side of the front face as going to the outer peripheral side, the rear face side inclined face being formed in a rear face side outer peripheral edge portion having a second width dimension formed along an outer peripheral edge of the rear face, and
the first width dimension is shorter than the second width dimension.

9. The circuit board according to claim 1, wherein the base member is made of aluminum.

10. The circuit board according to claim 1, wherein the base member comprises a fixing part structured to fix a motor.

11. The circuit board according to claim 3, wherein the electronic component is a wafer level chip size package, and a ball grid array is provided as the terminal.

12. The circuit board according to claim 3, wherein the occupancy ratio occupying the front face of the base member of the copper foil forming the second wiring layer is 80%-90%.

13. The circuit board according to claim 5, wherein
the terminal of the electronic component comprises a plurality of terminals,
the plurality of the terminals is connected with the land and the dummy land formed in the first wiring layer,
heat of the electronic component is transmitted to the second wiring layer through the plurality of the terminals of the electronic component, the land and the dummy land connected with the terminals, and the via-hole-filling plating connected with the land and the dummy land via-hole-filling plating connected with the dummy land, and
the heat of the electronic component is radiated to the base member from the second wiring layer through an insulating layer between the second wiring layer and the base member.

14. The circuit board according to claim 13, wherein
the electronic component is a wafer level chip size package and is provided with a ball grid array as the terminal,
the first wiring layer is provided with the lands and the dummy land with which the ball grid array of the wafer level chip size package is connected,
50% or more of the lands and the dummy land with which the ball grid array is connected are conducted to the second wiring layer through the via-hole-filling plating and the dummy land via-hole-filling plating.

15. The circuit board according to claim 14, wherein the occupancy ratio occupying the front face of the base member of the copper foil forming the second wiring layer is 80%-90%.

16. The circuit board according to claim 6, wherein an occupancy ratio of copper foil forming the second wiring layer occupying a front face of the base member is larger than an occupancy ratio of copper foil forming the first wiring layer occupying the front face of the base member.

17. The circuit board according to claim 16, wherein
the insulating layer is laminated on the front face of the base member,
the second wiring layer is formed so as to be laminated on the insulating layer,
heat of the electronic component is transmitted to the second wiring layer through the terminal of the electronic component, the land connected with the terminal, and the via-hole-filling plating connected with the land, and
the heat of the electronic component is radiated from the second wiring layer to the base member through the insulating layer.

18. The circuit board according to claim 17, wherein
the first wiring layer comprises a dummy land which is connected with an unused terminal among terminals of the electronic component,
the dummy land is connected with the second wiring layer through dummy land via-hole-filling plating which is formed at a position overlapped with the dummy land when viewed in the laminated direction,
heat of the electronic component is transmitted to the second wiring layer through the terminal of the electronic component, the dummy land connected with the terminal, and the dummy land via-hole-filling plating connected with the dummy land, and
the heat of the electronic component is radiated to the base member from the second wiring layer through the insulating layer.

19. The circuit board according to claim 6, wherein
the insulating layer is laminated on the front face of the base member,
the second wiring layer is formed so as to be laminated on the insulating layer,
heat of the electronic component is transmitted to the second wiring layer through the terminal of the electronic component, the land connected with the terminal, and the via-hole-filling plating connected with the land, and
the heat of the electronic component is radiated from the second wiring layer to the base member through the insulating layer.

20. The circuit board according to claim 19, wherein
the first wiring layer comprises a dummy land which is connected with an unused terminal among terminals of the electronic component,
the dummy land is connected with the second wiring layer through dummy land via-hole-filling plating which is formed at a position overlapped with the dummy land when viewed in the laminated direction,
heat of the electronic component is transmitted to the second wiring layer through the terminal of the electronic component, the dummy land connected with the terminal, and the dummy land via-hole-filling plating connected with the dummy land, and
the heat of the electronic component is radiated to the base member from the second wiring layer through the insulating layer.
